(19) United States
(12) Patent Application Publication
(10) Pub. No.: US 2025/0202441 A1
(43) Pub. Date: Jun. 19, 2025

(54) AMPLIFIER ARRANGEMENT AND METHOD FOR AMPLIFIER ARRANGEMENT WITH SET CURRENT AT CONTROL INPUT OF THE AMPLIFIER ARRANGEMENT IN DEPENDENCE ON AN OUTPUT CURRENT OF THE AMPLIFIER ARRANGEMENT

(71) Applicant: Advantest Corporation, Tokyo (JP)

(72) Inventor: Rudi BAUER, Eiselfing (DE)

(21) Appl. No.: 19/070,732

(22) Filed: Mar. 5, 2025

Related U.S. Application Data
(63) Continuation of application No. PCT/EP2022/074659, filed on Sep. 5, 2022.

(51) Int. Cl. H03F 3/04; H03F 1/52

(52) U.S. Cl. CPC H03F 3/04; H03F 1/52

(57) ABSTRACT

Embodiments according to the invention comprise an amplifier arrangement the amplifier arrangement including an amplifier, wherein the amplifier is configured to be controlled by a voltage at a control input of the amplifier arrangement and a current adjustment circuit, wherein the current adjustment circuit is configured to set, a current at the control input of the amplifier arrangement in dependence on, an output current of the amplifier arrangement.

### CROSS-REFERENCES TO RELATED APPLICATIONS

This application is a continuation of copending International Application No. PCT/EP2022/074659, filed Sep. 5, 2022, which is incorporated herein by reference in its entirety.

Embodiments according to the invention are related to amplifier arrangements and methods for amplifier arrangements with set currents at the control inputs of the amplifier arrangements in dependence on output currents of the amplifier arrangements.

Further embodiments according to the invention comprise, address and/or are related to a two terminal pair network for high voltage applications or high current applications.

### BACKGROUND OF THE INVENTION

In many cases, technical devices have to be tested before being used in their respective target application. In order to provide cost-effective and reliable testing results, automated test equipments, ATEs, may be used. Cost and complexity may often increase if devices have to be tested with high voltages or high currents. One main challenge is the provision of such voltages and currents with good accuracy. Hence, often complex and costly amplifier setups may be required.

Therefore, it is desired to get a concept for providing high voltages and/or high currents, for example for device testing, which makes a better compromise between a complexity, an efficiency and costs.

### SUMMARY

An embodiment may have an amplifier arrangement, the amplifier arrangement comprising: an amplifier, wherein the amplifier is configured to be controlled by a voltage at a control input of the amplifier arrangement; and a current adjustment circuit, wherein the current adjustment circuit is configured to set a current at the control input of the amplifier arrangement in dependence on an output current of the amplifier arrangement.

Another embodiment may have an amplifier system comprising an amplifier arrangement according to the invention; wherein the amplifier system comprises a module, wherein the module is configured to be coupled with the control input of the amplifier arrangement; wherein the module is configured to provide the voltage to the control input of the amplifier arrangement; and wherein the module is configured to determine an information about the current at the control input of the amplifier arrangement.

Another embodiment may have a method for an amplifier arrangement, the method comprising: controlling an amplifier of the amplifier arrangement with a voltage at a control input of the amplifier arrangement; and setting a current at the control input of the amplifier arrangement in dependence on an output current of the amplifier arrangement.

Another embodiment may have a non-transitory digital storage medium having a computer program stored thereon to perform the method for an amplifier arrangement, the method comprising: controlling an amplifier of the amplifier arrangement with a voltage at a control input of the amplifier arrangement; and setting a current at the control input of the amplifier arrangement in dependence on an output current of the amplifier arrangement, when said computer program is run by a computer.

Embodiments according to the invention comprise an amplifier arrangement, e.g. for use in combination with an automated test equipment, ATE, or for use in an ATE, the amplifier arrangement comprising an amplifier, e.g. an operational amplifier, e.g. an OP Amp, wherein the amplifier is configured to be controlled by a voltage at a control input of the amplifier arrangement, and a current adjustment circuit, e.g. being or comprising a voltage to current converter, wherein the current adjustment circuit is configured to set, e.g. to adjust, e.g. to induce, e.g. to provide; e.g. to generate; e.g. to effect, a current at the control input of the amplifier arrangement in dependence on, or, e.g. based on, or e.g. using, an output current of the amplifier arrangement.

As an example, the current adjustment circuit may be configured to mirror back the output current of the amplifier arrangement, e.g. in the form of a current associated with the output current, to the control input of the amplifier arrangement, for example being coupled with a control input of the amplifier. Optionally, the current adjustment circuit, may be configured to transfer an information about the output current of the amplifier (or amplifier arrangement) from a high voltage side of the amplifier (or amplifier arrangement) to a low voltage side of the amplifier (or amplifier arrangement).

The inventors recognized that an input-sided functionality of an amplifier arrangement or amplifier system may be used in order to determine an information about output signals of the amplifier arrangement. As explained before, the amplifier of the amplifier arrangement may be controlled by the voltage at the control input of the amplifier arrangement. This voltage may, for example, be provided by a module, e.g. a channel module, in order to reach a specific output voltage.

Furthermore, in many applications, a functionality to determine the input current, or in other words the current at the control input of the amplifier arrangement, may be available, for example provided by the module. The inventors recognized that for example for voltage controlled amplifiers, the input current of the amplifier arrangement may provide an additional degree of freedom that may be exploited in order to determine an information about the output current of the amplifier arrangement, since the input current may not be necessary for directly controlling the amplifier.

Therefore, the inventive amplifier arrangement comprises the current adjustment circuit which is configured to set the current at the control input of the amplifier arrangement in dependence on the output current of the amplifier arrangement. In simple words, the output current may be mirrored back, for example as a downscaled version, from the high voltage side of the amplifier arrangement to the low voltage side of the amplifier arrangement, such that an available measurement functionality on the low voltage side may be used to determine an information about the output current by determining the current at the control input, such that no additional dedicated measurement channel for the output current may be necessary.

According to further embodiments of the invention, a control input of the amplifier, e.g. OP Amp, is a high impedance input, e.g. an input having an approximately infinite impedance; e.g. such that an input current of the amplifier is approximately zero. Furthermore, the control input of the amplifier is coupled with the control input of the amplifier arrangement.

A high input impedance of the amplifier may prevent a current flow of the set current into the amplifier. Such a current flow may result in a difference between a measured current at the low voltage side of the amplifier arrangement, e.g. by a module or a channel thereof, and the set current, such that an information about the output current may be distorted.

According to further embodiments of the invention, the amplifier arrangement comprises a measurement circuit, e.g. a current-to-voltage converter, and the measurement circuit is coupled with an output of the amplifier, e.g. coupled between the output of the amplifier and the output of the amplifier arrangement. Furthermore, the measurement circuit is configured to provide, e.g. within a reasonable tolerance, an information, e.g. an analog signal representing the output current, about the output current of the amplifier arrangement, and e.g. accordingly an information about the output current of the amplifier, to the current adjustment circuit, e.g. to provide a voltage, associated with the output current of the amplifier, to the current adjustment circuit, in order to determine, e.g. adjust or e.g. set, the current at the control input of the amplifier arrangement.

According to further embodiments of the invention, the measurement circuit is configured to be adjusted, e.g. based on an external signaling, e.g. based on current range control bits, for evaluating, e.g. converting to an analog signal, the output current of the amplifier arrangement in a plurality of predetermined current ranges, e.g. current ranges of at least and at most +/−1 mA, +/−100 uA and/or +/−10 uA. Hence, the amplifier arrangement may be used for a plurality of current ranges, providing a good flexibility. Furthermore, such a current range changing may be signaled by application bits, e.g. control bits, e.g. Ctrl Bits. In other words, application specific, outer signaling may allow a simple current range adaptation.

According to further embodiments of the invention, the measurement circuit is a current-to-voltage converter, e.g. comprising a shunt resistor and a circuit for providing a voltage signal describing a voltage drop across the shunt resistor (e.g. for providing a voltage signal which is linearly dependent on, or proportional to the voltage drop across the shunt resistor, and the current adjustment circuit is a voltage-to-current converter, e.g. a voltage-controlled current source. In general, measurement circuit and current adjustment circuit may be corresponding, e.g. matching circuitries, such that the output of the measurement circuit may be the input of the current adjustment circuit. A voltage as intermediate information transmission parameter may allow an efficient mirroring of the current information form the high voltage of the low voltage side of the amplifier.

According to further embodiments of the invention, the measurement circuit is configured to provide an information, e.g. in the form of a voltage, about the output current of the amplifier arrangement to the current adjustment circuit in order to set the current at the control input of the amplifier arrangement to be a scaled version (e.g. a proportionally scaled version; e.g. a scaled current that is proportional to the output current; e.g. a version of the current having a smaller amplitude at least by a factor of 10 or at least by a factor of 50; e.g. a scaled version of the output current adapted for a measurement range of a module coupled with the control input of the amplifier arrangement; e.g. a downscaled version, e.g. downscaled at least by a factor of 10) of the output current of the amplifier arrangement, e.g. such that a comparatively larger output current results in, or translates to, or causes a comparatively smaller current at the control input of the amplifier arrangement.

Providing a scaled version of the output current may simplify a measurement of the scaled current. For example, in the case of high output currents a measurement thereof with good accuracy may be difficult. However, a measurement of a for example down-scaled version thereof may be performed with smaller costs, complexity and/or accuracy.

According to further embodiments of the invention, the amplifier arrangement comprises a voltage adaptation circuit, e.g. a voltage divider, and the voltage adaptation circuit is coupled with an output of the amplifier arrangement or with an output of the amplifier. Furthermore, the voltage adaptation circuit is configured to provide, e.g. to a module or to a sense pin of the module, a voltage that is associated with, e.g. that is proportional to; e.g. that is a downscaled version of, e.g. downscaled by a factor of at least 10, an output voltage of the amplifier arrangement or that is associated with, e.g. that is proportional to; e.g. that is a downscaled version of, e.g. downscaled by a factor of at least 10, an output voltage of the amplifier.

Optionally, the voltage adaptation circuit may be configured to provide a version of the output voltage with reduced amplitude and/or to provide a down-scaled version of the output voltage, e.g. to a module coupled with the control input of the amplifier arrangement and/or for example to the sense pin of the module.

Hence, a feedback information about the output voltage may be available, such that a desired output voltage may be set with good accuracy. Based on the information about the output voltage, the voltage at the control input of the amplifier arrangement may be set.

According to further embodiments of the invention, the amplifier is configured to provide an output voltage of the amplifier arrangement, such that the output voltage is at least by a factor of 10 or at least by a factor of 50 larger than the voltage at the control input of the amplifier arrangement.

Hence, embodiments according to the invention may address applications wherein large voltage amplification factors and/or large output voltages may be necessary. Furthermore, embodiments may allow to drive a high voltage output with a low voltage input without requiring complex and/or additional measurement circuits, for example without requiring complex and/or additional measurement circuits whilst providing a desired voltage and a desired current, with high accuracy, e.g. within acceptable tolerances, and with good robustness.

According to further embodiments of the invention, the amplifier is configured to provide the output current of the amplifier arrangement, such that the output current is at least by a factor of 10 or at least by a factor of 50 larger than the current that is provided at the control input of the amplifier arrangement, and/or such that a maximum output current of the amplifier is at least by a factor of 10, or at least by a factor of 50, larger than a maximum output current of a channel module coupled to the input of the amplifier arrangement.

Hence, embodiments according to the invention may address applications wherein large current amplification factors and/or large output voltages may be necessary. Furthermore, embodiments may allow to determine or even to control high output currents without requiring complex and/or additional measurement circuits or measurement channels.

According to further embodiments of the invention, the amplifier arrangement comprises a safety module and the safety module is configured to disconnect the amplifier from an energy supply, e.g. a supply voltage, e.g. based on a safety control signal.

Optionally, the safety module may be configured to switch between a first operating mode in which the amplifier is connected to the power supply and a second operating mode in which the amplifier is disconnected from the power supply, e.g. in response to an activation of a safety signal. Hence, high voltages and/or high currents may be provided with high safety.

According to further embodiments of the invention, the amplifier arrangement comprises an output line and a guard line, e.g. a driven shield, and the output line is configured to provide an output signal, e.g. being or comprising the output voltage and/or the output current, of the amplifier arrangement. Furthermore, the guard line is configured to be provided, e.g. driven, with a voltage associated with, e.g. approximately equal to the voltage of, the output signal of the amplifier arrangement, and the guard line is arranged in a surrounding of, e.g. in close proximity to, e.g. next to, the output line, in order to reduce or prevent a leakage current from the output line. Therefore, a reduction of output signal accuracy may be prevented by mitigating leaking currents. This may allow usage of inventive amplifier arrangements for applications with high output signal accuracy requirements.

According to further embodiments of the invention, the amplifier arrangement comprises a multiplexer and the multiplexer is configured to provide an output signal of the amplifier arrangement, e.g. being or comprising the output voltage and/or the output current of the amplifier arrangement, and optionally a voltage associated with, e.g. approximately equal to the voltage of, the output signal of the amplifier arrangement, e.g. associated with the output voltage of the amplifier arrangement, to a respective output channel of a plurality of output channels. Furthermore, a respective output channel comprises an output line, for providing the output signal, and a corresponding guard line, wherein the guard line is configured to be provided with, e.g. driven by, the voltage associated with the output signal, in order to prevent a leakage of current from the output line.

Hence a plurality of output channels may be provided with accurate voltages and/or currents, together with respective guard signals.

According to further embodiments of the invention, the multiplexer comprises a first set of switches and a second set of switches, wherein a respective switch of the first set of switches is configured to provide the voltage, associated with, e.g. approximately equal to the voltage of, the output signal of the amplifier arrangement, to a guard line of a respective output channel, wherein a respective switch of the second set of switches is configured to provide the output signal of the amplifier arrangement to an output line of a respective channel, and wherein the switches of the second set of switches comprise a T-switch topology, e.g. a topology comprising two, for example analog, switches in series, with a third switch connected between a common connection of the two series switches and a reference potential, e.g. ground, e.g. earth.

The inventors recognized that usage of the T-switch topology may allow to reduce cross talk, e.g. compared to single switch topologies. In other words, an advantage may be less cross talk compared to single switches. A single switch may have a capacitance between switch contacts. With T-switches this crosstalk can, for example, be improved and may be good or even be pretty good.

According to further embodiments of the invention, the amplifier arrangement comprises a calibration circuit, e.g. a calibration resistor, e.g. an internal calibration resistor, and the calibration circuit is configured to be coupled with an output of the amplifier arrangement, in order to allow for a determination of a calibration information for the current at the control input of the amplifier arrangement.

As an example, a voltage over a calibration resistor of the calibration circuit, acting as a load for the amplifier, may be measured, in order to determine the output current of the amplifier. For example using a table or a scaling factor, this output current may be associated with the current at the control input measured under the same conditions. Furthermore, such measurements may be performed in certain time intervals. The calibration circuit may allow to re-calibrate the amplifier arrangement over its lifespan.

According to further embodiments of the invention, the amplifier arrangement is configured to support a first operating mode, e.g. a voltage mode with current clamping, in which the amplifier arrangement provides an output signal comprising a predetermined voltage, e.g. defined by a voltage at the control input of the amplifier arrangement, and a current within a predetermined current interval (e.g. between zero and a maximum current, wherein, for example, a channel module providing a control voltage at the control input of the amplifier arrangement and evaluating the current at the control input of the amplifier arrangement may control the operation and may, for example, reduce the control voltage in case the current at the control input of the amplifier arrangement reaches or exceeds a predetermined maximum value).

Furthermore, the amplifier arrangement is configured to support a second operating mode, e.g. a current mode with voltage clamping, in which the amplifier arrangement provides an output signal comprising a predetermined current and a voltage within a predetermined voltage interval (e.g. between zero and a maximum voltage, wherein, for example, a channel module providing a control voltage at the control input of the amplifier arrangement and evaluating the current at the control input of the amplifier arrangement may control the operation and may, for example, control the control voltage such that the current at the control input of the amplifier arrangement takes a predetermined target value, while keeping the control voltage at the control input of amplifier arrangement or a feedback voltage within a predetermined range).

Hence, an amplifier arrangement according to embodiments may allow to support a plurality of operating modes and therefore application requirements. In addition, the amplifier arrangement comprises a good flexibility. The inventive mirroring of the output current to the low voltage side of the amplifier may allow to provide this plurality of operating modes with only limited impact on complexity.

Further embodiments according to the invention comprise an amplifier system, the amplifier system comprising an amplifier arrangement according to any of the embodiments as disclosed herein, wherein the amplifier system further comprises a module, e.g. a channel module, e.g. a channel module comprising one or more channels, wherein the module is configured to be coupled with the control input of the amplifier arrangement. Furthermore, the module is configured to provide the voltage, e.g. the voltage at the control input of the amplifier, to the control input of the amplifier arrangement and the module is configured to determine, e.g. using a current measurement circuit of the module, an information about the, e.g. set, current at the control input of the amplifier arrangement, e.g. to measure the set current.

Hence, the module may control the output of the amplifier arrangement by providing the voltage at the input of the amplifier arrangement. In addition, e.g. by measuring the current at the control input of the amplifier arrangement, the module may determine an information about the output current of the amplifier arrangement. Therefore, the module may control and monitor the amplifier arrangement.

According to further embodiments of the invention, the module is configured to obtain, or, for example, to determine or, for example, to measure, an information about an output voltage of the amplifier arrangement.

Optionally, the module may be configured to obtain a feedback signal, e.g. an analog feedback signal, a signal value of which represents the output voltage of the amplifier and/or of the amplifier arrangement, wherein the module may, for example, use the information about the output voltage of the amplifier arrangement for a “sense-type” voltage regulation.

Hence, the module may act as a feedback controller for the output voltage of the amplifier arrangement. This way, the output voltage may be provided with good accuracy.

According to further embodiments of the invention, the module comprise a force pin (e.g. of an analog ATE pin, e.g. of a single low voltage pin; e.g. of a driving analog ATE pin) and the force pin is configured to be coupled with the control input of the amplifier arrangement, e.g. using or via a transmission line from a force pin of the module to the control input of the amplifier arrangement. Furthermore, the module is configured to provide the voltage to the control input of the amplifier arrangement using the force pin and the current adjustment circuit is configured to provide the set current to the force pin, e.g. in order to allow for a determination of the information about the set current at the control input of the amplifier arrangement by the channel module. As an example, this may allow to determine an information about the output current of the amplifier arrangement, e.g. in order to allow the channel module to adjust the voltage provided to the control input of the amplifier arrangement.

According to further embodiments of the invention, the module comprises a sense pin (e.g. of an analog ATE pin, e.g. of a single low voltage pin; e.g. of a driving analog ATE pin) and the sense pin is coupled, e.g. directly or via an intermediate circuit, like, for example, a voltage divider and/or a potential separation, with an output of the amplifier arrangement, e.g. to sense an actual voltage at the output of the amplifier arrangement; e.g. to implement a closed-loop control of the voltage at the output of the amplifier arrangement.

Furthermore, the sense pin is associated with, or e.g. corresponding to; or e.g. related to, the force pin (e.g. wherein the sense pin is configured to measure or to detect or to receive a response signal or a signal change associated with or caused by or induced by or using a stimulus or a signal provided by or induced by the force pin), but the sense pin is different from the force pin. In addition, the module is configured to obtain the information about, e.g. to measure, the output voltage of the amplifier arrangement using the sense pin.

Hence, using the module, a control signal, namely the voltage for the control input, may be provided by the force pin, and a corresponding output voltage may be measured using the sense pin. However, a functionality using the force pin to measure an input current may be used to determine an information about the output current by mirroring back the output current as a downscaled version thereof to the control input using the current adaptation circuit (and optionally the measurement circuit). Hence, no additional sense of another module may be necessary for the provision of an information about the output current.

According to further embodiments of the invention, the module is configured to control a slew rate and/or a bandwidth of the amplifier. In general the module may provide any control or adaptation functionality necessary for the amplifier arrangement and hence the amplifier.

According to further embodiments of the invention, the amplifier arrangement is a high voltage circuit, e.g. a circuit configured to provide an output voltage of at least 60V, or a circuit configured to provide an output voltage of at least 100V, or a circuit configured to provide at least 200V, or a circuit configured to provide at least 500V, or a circuit configured to provide at least 900V, or a circuit configured to provide at least 1000V; e.g. a circuit configured to provide a high output voltage e.g. a voltage with an amplitude which is at least by a factor of 10 or at least by a factor of 50 larger than a maximum output voltage provided by the module (which may be considered as a low output voltage).

Furthermore, the module is a low voltage circuit (e.g. a circuit configured to provide a maximum output voltage of no more than 7V, or a circuit configured to provide a maximum output voltage of no more than 12V, or a circuit configured to provide a maximum output voltage of no more than 15V, or a circuit configured to provide a maximum output voltage of no more than 30V), comprising a low voltage output (e.g. comprising or being the force pin, e.g. an output configured to provide a maximum output voltage of no more than 7V, or an output configured to provide a maximum output voltage of no more than 12V, or an output configured to provide a maximum output voltage of no more than 15V, or an output configured to provide a maximum output voltage of no more than 30V), wherein the low voltage output is configured to provide an output voltage to the control input of the amplifier arrangement; and

Optionally, the module comprises, as an example, a current measurement circuit, wherein the current measurement circuit is configured to measure the (e.g. set) current at the control input of the amplifier arrangement (e.g. using the force pin). Moreover, the low voltage circuit is configured to drive the high voltage circuit.

According to further embodiments of the invention, a voltage range of an output voltage of the amplifier exceeds a voltage range of an output voltage of the module at least by a factor of 10 or at least by a factor of 50, e.g. such that maximum output voltage of the amplifier is at least by a factor of 10 or at least by a factor of 50 larger than a maximum output voltage of the module. Hence using a low voltage module a high voltage amplifier arrangement may be driven.

Further embodiments according to the invention comprise a method for an amplifier arrangement, e.g. for use in combination with an automated test equipment, ATE, or for use in an ATE, wherein the method comprises controlling an amplifier, e.g. an OP Amp, of the amplifier arrangement with a voltage at a control input of the amplifier arrangement and setting, e.g. adjusting, e.g. inducing, e.g. providing; e.g. generating; e.g. effecting, a current at the control input of the amplifier arrangement in dependence on an output current of the amplifier arrangement.

The method as described above is based on the same considerations as the above-described amplifier arrangement. The method can, by the way, be completed with all features and functionalities, which are also described with regard to the amplifier arrangement.

Further embodiments according to the invention comprise a computer program for performing any of the methods as disclosed herein, when the computer program runs on a computer.

### BRIEF DESCRIPTION OF THE DRAWINGS

Embodiments of the present invention will be detailed subsequently referring to the appended drawings, in which:

FIG. 1 shows a schematic view of an amplifier arrangement according to embodiments of the invention;

FIG. 2 shows a schematic view of an amplifier system according to embodiments of the invention;

FIG. 3 shows a block diagram of a method according to embodiments of the invention;

FIG. 4 shows a schematic view of an amplifier system comprising an amplifier arrangement and a module according to embodiments of the invention;

FIG. 5 shows a schematic view of an amplifier system comprising an amplifier arrangement and a module with further optional features, according to embodiments of the invention;

FIG. 6 shows a schematic view of another amplifier system according to embodiments of the invention;

FIG. 7 shows schematic view of an amplifier according to embodiments of the invention;

FIG. 8 shows a schematic view of an amplifier system with optional safety features according to embodiments of the invention;

FIG. 9 shows a schematic view of a security switch according to embodiments of the invention;

FIG. 10(a) shows a further examples for amplifiers; and

FIG. 10(b) shows an example for dimensions of an amplifier in a schematic view of an amplifier according to embodiments of the invention.

### DETAILED DESCRIPTION OF THE INVENTION

Equal or equivalent elements or elements with equal or equivalent functionality are denoted in the following description by equal or equivalent reference numerals even if occurring in different figures.

In the following description, a plurality of details is set forth to provide a more throughout explanation of embodiments of the present invention. However, it will be apparent to those skilled in the art that embodiments of the present invention may be practiced without these specific details. In other instances, well-known structures and devices are shown in block diagram form rather than in detail in order to avoid obscuring embodiments of the present invention. In addition, features of the different embodiments described herein after may be combined with each other, unless specifically noted otherwise.

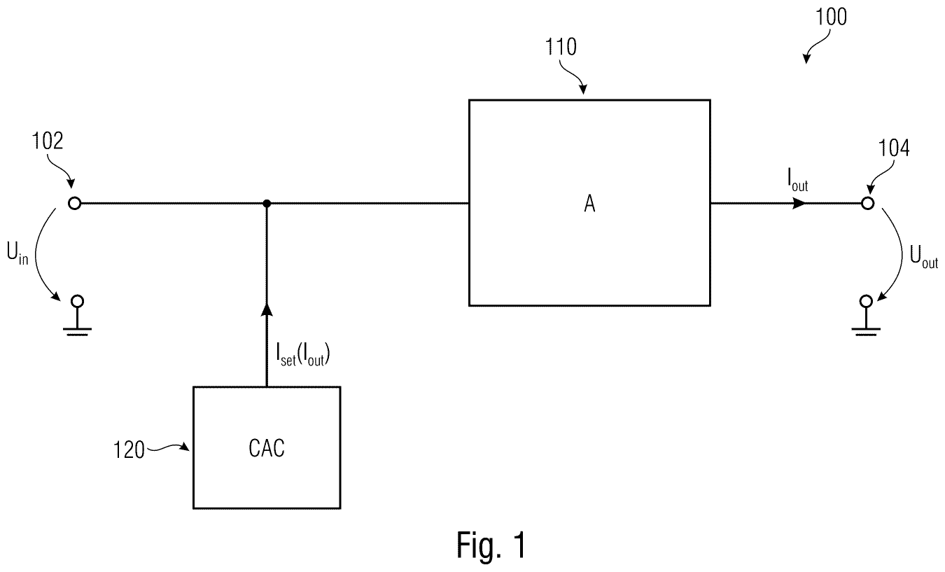

FIG. 1 shows a schematic view of an amplifier arrangement according to embodiments of the invention. FIG. 1 shows amplifier arrangement 100 comprising an amplifier, A, 110 and a current adjustment circuit, CAC, 120.

The amplifier 110 is configured to be controlled by a voltage Uᵢₙ at a control input 102 of the amplifier arrangement 100. As an example, the amplifier 110 may be provided with a low voltage input signal Uᵢₙ at control input 102 and may amplify the signal to a high voltage output signal Uₒᵤₜ at an output 104 of the amplifier arrangement.

The current adjustment circuit 120 is configured to set a current Iₛₑₜ at the control input 102 of the amplifier arrangement 100 in dependence on an output current Iₒᵤₜ of the amplifier arrangement.

It is to be noted that the voltages Uᵢₙ, Uₒᵤₜ and the currents Iₛₑₜ, Iₒᵤₜ may depend on outer circuitry, e.g. a module being coupled with input 102 and/or a load or measurement circuitry being coupled with output 104 and that these entities are here shown altogether and without further outer circuitry as examples for providing a better understanding of embodiments according to the invention.

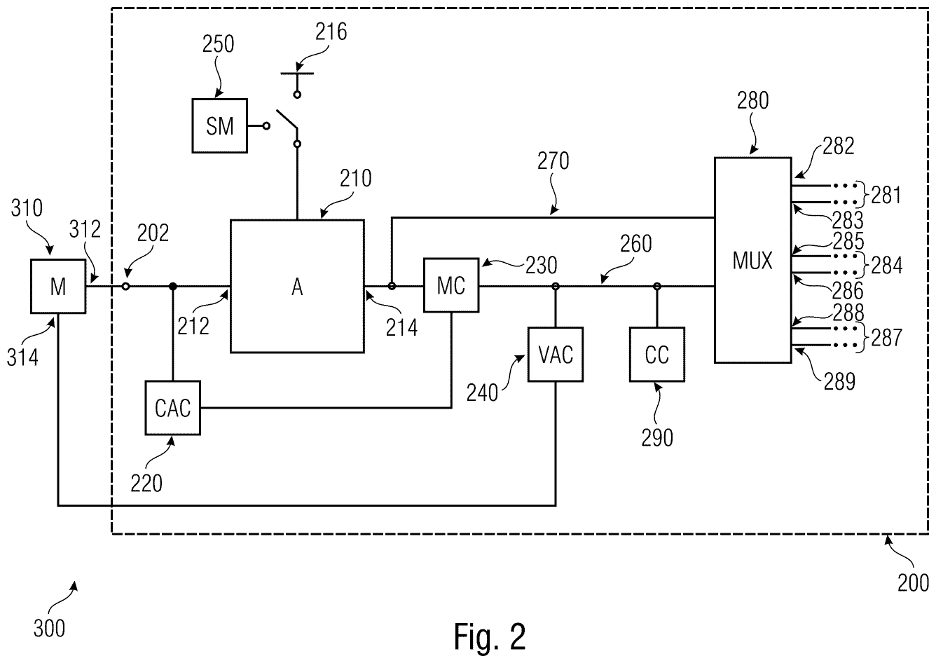

FIG. 2 shows a schematic view of an amplifier system according to embodiments of the invention. FIG. 2 shows amplifier system 300 comprising a module 310 and an amplifier arrangement 200, the amplifier arrangement comprising an amplifier, A, 210 and a current adjustment circuit, CAC, 220. Amplifier 210 and current adjustment circuit 220 may comprise the functionality as explained in the context of FIG. 1.

As an optional feature, the module 310 is coupled with the control input 202 of the amplifier arrangement and the module is configured to provide the voltage to the control input of the amplifier arrangement. Furthermore, the module is configured to determine an information about the current at the control input 202 of the amplifier arrangement 200. Hence, module 310 may be configured to determine an information about an output current of the amplifier arrangement 200 and/or the amplifier 210.

As an optional feature, a control input 212 of the amplifier 210, coupled with the control input 202 of the amplifier arrangement, may be a high impedance input. Therefore, amplifier 210 may, for example, be an operational amplifier. Consequently, an input current of the amplifier 212 may, for example, be approximately zero, such that a current provided or set by the current adjustment circuit 220 may be fully provided to the control input 202, with only minor or approximately zero losses towards the amplifier 210. Without lost current towards amplifier 210, a determination of the output current based on the set current may be performed accurately.

As an additional, optional feature amplifier arrangement 200 comprises a measurement circuit, MC, 230 which is coupled with an output 214 of the amplifier 210. The measurement circuit 230 may be configured to measure the output current of the amplifier arrangement 200, and therefore, at least approximately, the output current of the amplifier 210. As an example, the measurement circuit 230 may determine a voltage drop over a resistor which is coupled serially with the output 214 of the amplifier arrangement.

However, it is to be noted that embodiments are not limited to a specific type of measurement. In general, measurement circuit 230 is configured to determine an information about the output current of the amplifier arrangement in order to provide this information to the current adjustment circuit 220.

Based on this information, the current adjustment circuit 220 may adjust the current at the control input 202 of the amplifier arrangement. Based on a measurement of this current at the control input of the amplifier arrangement, an information about the original measurement of the output current may be obtained.

As another optional feature, the measurement circuit 230 may be a current-to-voltage converter and the current adjustment circuit 220 may be a voltage-to-current converter. In other words and in general, the measurement circuit 230 and the current adjustment circuit 220 may be corresponding circuits, such that a signal conversion, e.g. an analog signal conversion, from a measured current (or a respective measurement entity thereof, e.g. a voltage) to a set current may be provided.

As another optional feature, the set current at the control input 202 of the amplifier arrangement may be a scaled version of the output current of the amplifier arrangement. As an example, based on a measurement information from the measurement circuit 230, e.g. a voltage, the current adjustment circuit 220 may set the current at the control input 202 to be a down scaled version of the current corresponding to the measurement information. In other words, embodiments may comprise a current translation from a high voltage side of the amplifier 210 to a low voltage side of the amplifier.

As another optional feature, the amplifier arrangement 200 comprises a voltage adaptation circuit, VAC, 240, The voltage adaptation circuit 240 may, for example, be coupled with an output of the amplifier arrangement or with an output of the amplifier, e.g. via the measurement circuit 230.

The voltage adaptation circuit 240 is configured to provide and information about an output voltage of the amplifier arrangement 200. As an example, the information may be a voltage that is associated with the output voltage of the amplifier arrangement or that is associated with an output voltage of the amplifier. Optionally, voltage adaptation circuit 240 may comprise a voltage divider and may provide a voltage that is proportional, but for example, significantly smaller, than the output voltage of the amplifier arrangement. Hence, based on such a voltage feedback a voltage regulation may be performed.

As another optional feature, the module comprises a force pin 312 which is coupled with the control input 202 of the amplifier arrangement and the module is configured to provide the voltage to the control input 202 of the amplifier arrangement using the force pin. Furthermore, the current adjustment circuit 220 is configured to provide the set current to the force pin 312. Hence, the force pin may be used for providing a control signal, namely the voltage at the control input and at the same time for receiving an information about an output current of the amplifier arrangement, namely the set current depending on the output current.

As shown, the voltage adaptation circuit 240 may be coupled with the module 310. In addition, the module may comprise a sense pin 314. In general, the sense pin may be coupled with an output of the amplifier arrangement 200. Accordingly, the module may be configured to obtain an information about an output voltage of the amplifier arrangement, for example, as shown in FIG. 2 via or using sense pin 314.

As another optional feature, the amplifier 210 may be configured to provide an output voltage of the amplifier arrangement 200, such that the output voltage is at least by a factor of 10 or at least by a factor of 50 larger than the voltage at the control input 202 of the amplifier arrangement. Hence, embodiments may address large amplification factors, such that a low input voltage may drive a high output voltage.

As another optional feature, the amplifier 210 may be configured to provide the output current of the amplifier arrangement 200, such that the output current is at least by a factor of 10 or at least by a factor of 50 larger than the current that is provided at the control input 202 of the amplifier arrangement, and/or such that a maximum output current of the amplifier is at least by a factor of 10, or at least by a factor of 50, larger than a maximum output current of a channel module coupled to the input of the amplifier arrangement.

Accordingly, embodiments may address high current applications wherein a large output current may be translated or mirrored to a low current at the control input 202 for a measurement thereof or wherein the large output current is monitored using the low current at the control input 202, e.g. being a down-scaled version of the output current.

As another optional example, amplifier arrangement 200 comprises a safety module, SM, 250 and the safety module is configured to disconnect the amplifier 210 from an energy supply 216. This may allow a safe and robust operation of the amplifier arrangement with regard to the high voltages and currents that may be provided.

As another optional feature, amplifier arrangement 200 comprises an output line 260 and a guard line 270. The output line may provide an output signal of the amplifier arrangement. The guard line is arranged in close proximity to the output line, the guard line may even surround the output line and may be provided with a voltage associated with, e.g. approximately equal to the voltage of, the output signal on the output line 260. Hence, leaking currents from the output line may be prevented or at least hindered. Consequently, the output signal may be provided with high accuracy, e.g. for well-defined testing conditions.

As another optional feature, the amplifier arrangement comprises a multiplexer, MUX, 280. Multiplexer 280 is configured to provide an output signal of the amplifier arrangement and a voltage associated with the output signal of the amplifier arrangement to a respective output channel of a plurality of output channels.

A respective output channel 281, 284, 287 comprises an output line 282, 285, 288, for providing the output signal, and a corresponding guard line 283, 286, 289, wherein the guard line is configured to be provided with the voltage associated with the output signal, in order to prevent a leakage of current from the output line. Hence, a plurality of devices may be addressed.

As another optional feature, the amplifier arrangement 200 comprises a calibration circuit, CC, 290. The calibration circuit is coupled with an output of the amplifier arrangement, in order to allow for determination of a calibration information for the current at the control input of the amplifier arrangement. As an example, the calibration circuit 290 may comprise a resistor and a switch which are coupled with a reference potential. Hence, without any other load, the output current may be determined using the calibration resistor (e.g. by measuring a voltage drop over the resistor) in order to calibrate the amplifier arrangement, e.g. with regard to the provided voltage at control input, and/or with regard to a relationship between current at control input and output current.

As another optional feature, the amplifier arrangement 200 may be configured to support a first operating mode in which the amplifier arrangement provides an output signal comprising a predetermined voltage and a current within a predetermined current interval and a second operating mode in which the amplifier arrangement provides an output signal comprising a predetermined current and a voltage within a predetermined voltage interval. In other words, the amplifier arrangement may be configured to provide a voltage mode with current clamping and a current mode with voltage clamping. Hence, embodiments may comprise a good flexibility for different testing scenarios.

As another optional feature, the module 310 may be configured to control a slew rate and/or a bandwidth of the amplifier 210.

As shown in FIG. 2 and as explained before, the module 310 may be configured to drive or to control the amplifier circuit 200. Therefore, a low voltage may be provided to the control input 202 of the amplifier arrangement on a low voltage side of the amplifier arrangement which may yield a high voltage at an output of the amplifier arrangement. Hence, in other words, the amplifier arrangement 200 may be a high voltage circuit and the module 310 may be a low voltage circuit comprising a low voltage output, wherein the low voltage output may be configured to provide an output voltage to the control input of the amplifier arrangement and wherein the low voltage circuit may be configured to drive the high voltage circuit.

As an example, a voltage range of an output voltage of the amplifier 210 may exceed a voltage range of an output voltage of the module 310 at least by a factor of 10 or at least by a factor of 50.

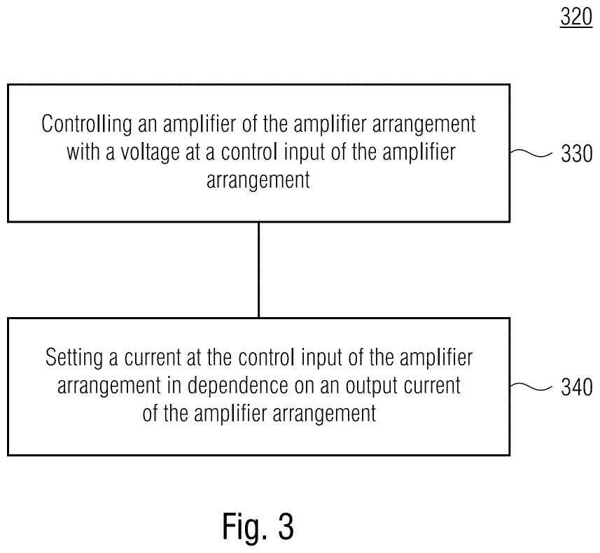

FIG. 3 shows a block diagram of a method according to embodiments of the invention. FIG. 3 shows method 320 for an amplifier arrangement, wherein the method comprises controlling 330 an amplifier of the amplifier arrangement with a voltage at a control input of the amplifier arrangement and setting 340 a current at the control input of the amplifier arrangement in dependence on an output current of the amplifier arrangement.

In the following embodiments according to the invention will be explained in different words. Furthermore new embodiments will be disclosed.

First of all problems that may be solved or addressed by embodiments of the invention or respective features of such embodiments will be discussed:

Embodiments according to the invention comprise, provide and/or are a simple way to get higher output voltages or higher output current from an analog ATE pin. One single low voltage pin can, for example, drive a high voltage or high current unit on the output. According to or using embodiments, it may be possible to extend voltages and currents while having many or even all the existing features available on the used driving analog ATE pin. The special function according to embodiments may, for example, be that a current measurement at a high side, e.g. a high voltage side of the amplifier arrangement, is mirrored back to the force pin of the driving analog pin, e.g. to the force pin of a module, for example, a low voltage module, wherein the module is driving the amplifier arrangement.

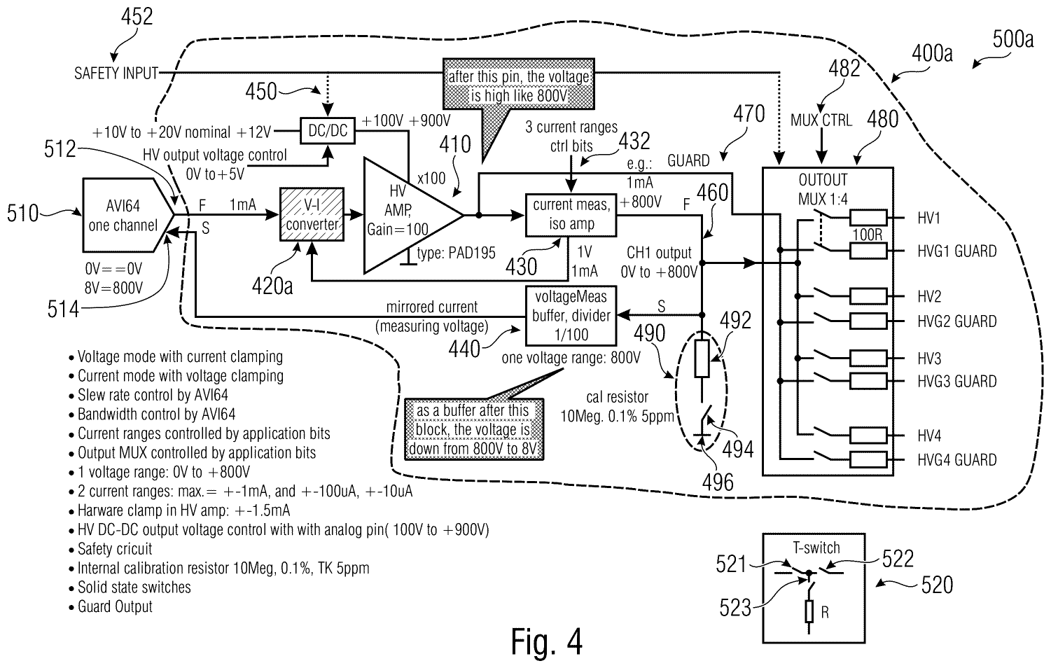

Next, a description of the construction and operation of embodiments according to the invention is provided. First however, reference is made to FIGS. 4 to 6.

FIG. 4 shows a schematic view of an amplifier system comprising an amplifier arrangement and a module according to embodiments of the invention. FIG. 4 shows amplifier system 500a comprising a module 510 which is as an example an AVI64 module (e.g. ADVANTEST V93000) comprising one channel, and an amplifier arrangement 400a.

It is to be noted that any information provided with regard to a specific design or configuration of features of embodiments of the invention, e.g. such as the module being an AVI64 module is to be seen as examples and furthermore, it is to be noted that embodiments may hence comprise elements having a similar or equal functionality as the examples shown herein. In the same spirit any, specific values named or presented herein are to be understood as examples. Accordingly, embodiments are not limited to a specific design and hence it is to be noted that any numbers or values given are to be understood as numbers or values with a tolerance of for example +/−1%, +/−5%, +/−10%, +/−50%, +/−100%, +/−500% and/or +/−1000%.

FIG. 4 shows specific examples for the elements of amplifier arrangements according to embodiments, namely amplifier arrangement 400a comprises an amplifier 410, as optionally shown in the form of a high voltage, HV, amplifier with an optional Gain of 100. As shown amplifier 410 may for example, be a PAD195.

Amplifier arrangement 400a further comprises a current adaptation circuit 420a, as optionally shown in the form of a V-I-Converter. The current adaptation circuit 420a is coupled with a force pin 512 of the module. Coupling may be provided via a control input of the amplifier arrangement (not shown). Hence, as explained before, the module 510 may provide a voltage to the amplifier 410 via a control input of the amplifier arrangement and may receive or determine a current provided or set by the current adaptation circuit 420a, in order to determine an information about an output current of the amplifier arrangement.

Amplifier arrangement 400a further comprises a measurement circuit 430, as optionally shown in the form of a current measurement unit (Current Meas iso amp) and a voltage adaptation circuit 440, as optionally shown in the form of a voltage measurement buffer, e.g. a voltage divider comprising a voltage division ration of 1:100, such that an output voltage from an output of the amplifier of for example 800V may be converted to a voltage of 8V, which is provided to a sense pin 514 of the module 510. Hence, the voltage adaptation circuit 440 may measure the output voltage, e.g. as shown the output voltage of a first channel, for example in an interval of [0, 800V], to provide a feedback information to the sense pin 514 of module 510.

As explained before, the measurement circuit 430 is coupled with the current adaptation circuit 420a, to provide a feedback information regarding the output current of amplifier 410 to the force pin 512 of module 510. In simple words, the output current may me mirrored as a scaled down version to the control input of the amplifier arrangement and hence the module 510. Examples for respective signal amplitudes are shown in FIG. 4.

Furthermore, the measurement unit 430 may be configured to receive a control signal 432 in order to switch between different operating modes, such that different current ranges may be addressed. Therefore control bits, e.g. application specific control bits, e.g. Ctrl Bits may be used.

In general, the measurement circuit may be configured to be adjusted for evaluating, the output current of the amplifier arrangement in a plurality of predetermined current ranges, e.g. 3 current ranges, e.g. of at least and at most +/−1 mA, +/−100 uA and/or +/−10 uA.

Amplifier arrangement 400a further comprises an output line 460 and a guard line 470. As explained before, the guard line 470 may be arranged in close proximity, e.g. surrounding, the output line, in order to prevent leakage currents. Therefore, guard line 460 is coupled with an output of amplifier 410.

As another optional feature, amplifier arrangement 400a comprises a multiplexer. Multiplexer 480 is provided with the guard line signal and the output signal, in order to direct such signals to a plurality of channels. Respective channels may each comprise, as optionally shown, a line for the output signal and guard line. Any form of multiplexer and any number of channels may be implemented. As shown a 1:4 multiplexer may be used, however 1:2 or other ratios may be used as well.

As shown with additional block 520, the multiplexer may comprise switches with a T-topology, e.g. a topology comprising two, for example analog, switches 521, 522 in series, with a third switch 523 connected between a common connection of the two series switches and a reference potential, e.g. ground, e.g. earth.

In general the multiplexer may comprise a first set of switches and a second set of switches, wherein a respective switch of the first set of switches is configured to provide the voltage, associated with the output signal of the amplifier arrangement, to a guard line of a respective output channel and wherein a respective switch of the second set of switches is configured to provide the output signal of the amplifier arrangement to an output line of a respective channel and wherein the switches of the second set of switches comprise a T-switch topology.

Amplifier arrangement 400a further comprises a safety module 450. As shown, optionally, a DC/DC converter may comprise the safety module 450, such that based on an activation of a safety signal 452 a supply voltage provided from the DC/DC converter to the amplifier 410 may be disconnected. As an example, the DC/DC converter may be provided with a nominal voltage of +12V, e.g. a voltage of at least +10V and at most +20V and may be provided with a high voltage output voltage control signal in an interval of [0V, . . . , 5V].

As an optional feature, the safety signal 452 may be provided to the multiplexer 480 as well, e.g. in order to disconnect the high voltage of the output line 460 from the channels of the multiplexer 480.

As another optional feature, amplifier arrangement 400a comprises a calibration circuit 490 comprising a calibration resistor 492 (Cal Resistor, having as an example a resistance of 10 Meg, with 0.1%, 5 ppm) which is coupled to a reference potential 496, e.g. ground via a switch 494. Hence, for example, in a situation without load, by closing switch 494 and measuring a voltage over resistor 492, the amplifier arrangement 400a may be calibrated.

As summed up in FIG. 4, the amplifier system 500a may comprise a voltage mode with current clamping, a current mode with voltage clamping, a slew rate control by the module (AVI64), a bandwidth control by the module (AVI64), current ranges control using, or by application bits, e.g. bits 432, an output multiplexer, MUX, control by or using application bits, e.g. bits 482, e.g. MUX control (CTRL) bits, a voltage range of at least 0V to at most +800V, a plurality of current ranges, e.g. 2 ranges, e.g. 3 ranges, e.g. max. =+−1 mA, and +−100 mA, +−10 uA, hardware clamp in the amplifier (HV amp): +−1.5 mA, HV DC-DC output voltage control with analog pin (100V to +900V), a safety circuit 450, an internal calibration resistor, e.g. having 10 Meg, 0.1% TK 5 ppm, solid state switches and/or a guard output, and/or for example, multiple guard outputs (MUX, HVGx GUARD).

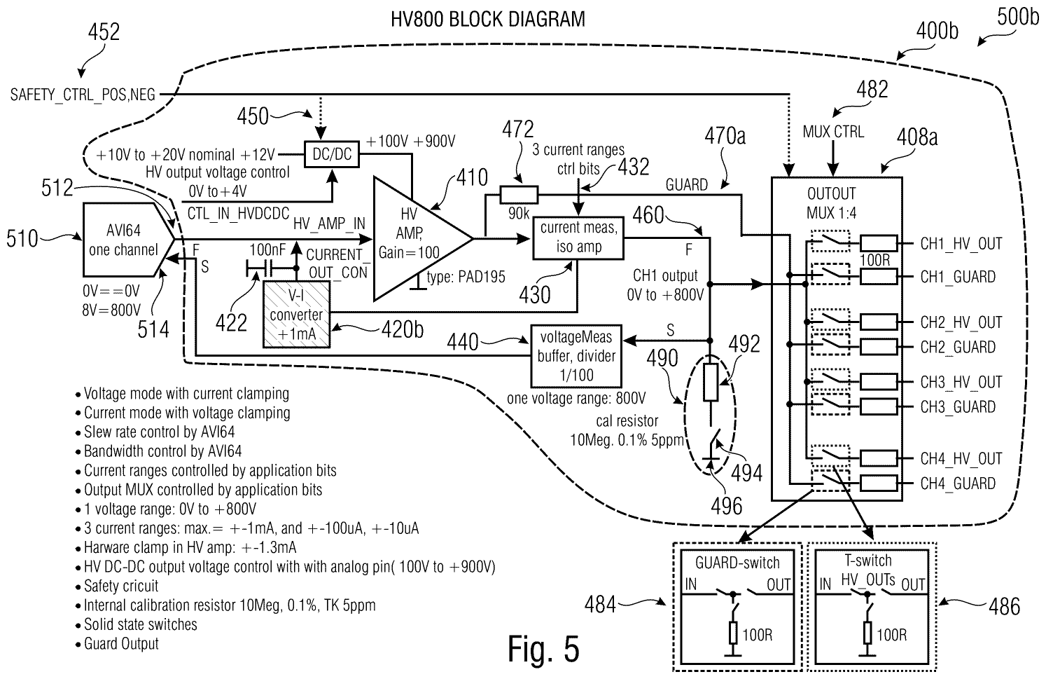

FIG. 5 shows a schematic view of an amplifier system comprising an amplifier arrangement and a module with further optional features, according to embodiments of the invention. FIG. 5 shows amplifier system 500b comprising amplifier arrangement 400b mainly comprising the elements as explained before. In comparison to FIG. 4, amplifier arrangement 400b comprises a resistor 472 between the guard line 470a and the amplifier 410 and the DC/DC converter may for example be provided with a HV output voltage output of at most 4V.

Furthermore, between the current adaptation circuit 420b and the force pin 512 of module 510 and amplifier 410, amplifier arrangement 400b comprises an additional capacitor coupled with a reference potential (422). In addition, as shown in FIG. 5, multiplexer 480a may comprise different kinds of switches, e.g. guard switches 484 for guard lines and T-switches 486 (e.g. corresponding to switch 520 shown in FIG. 4) for output lines.

As an example, hardware clamp in the amplifier 410 of amplifier arrangement 400b may comprise an interval of +−1.3 mA.

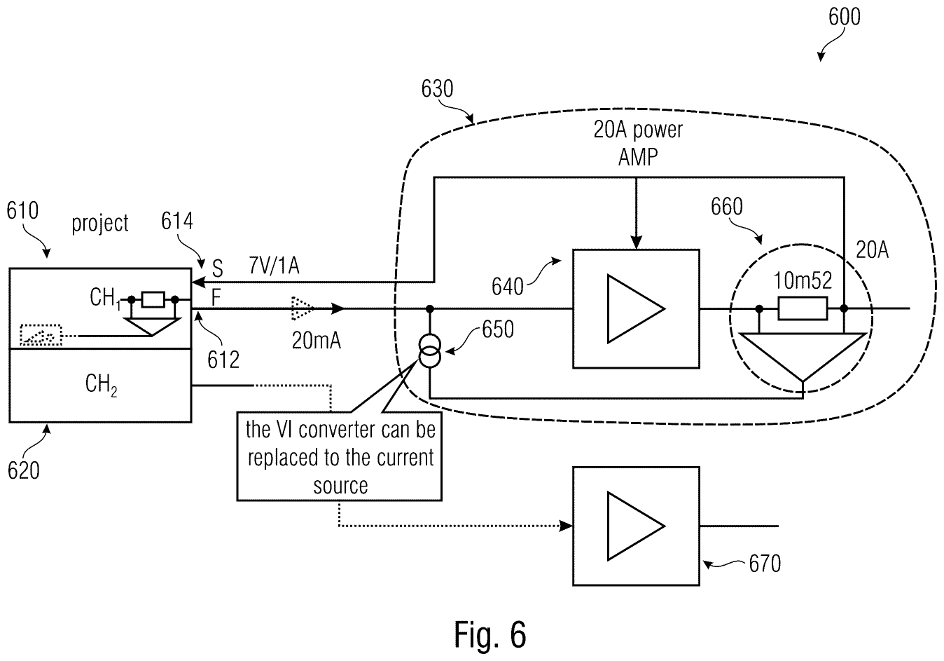

FIG. 6 shows a schematic view of another amplifier system according to embodiments of the invention. FIG. 6 shows amplifier system 600 comprising a first module 610, a second module 620, an amplifier arrangement 630, the amplifier arrangement comprising an amplifier 640, a current adaptation circuit 650 and a measurement circuit 660. The system 600 further comprises an additional amplifier 670. Module 610 comprises a force pin 612 and a sense pin 614.

Via force pin 612 a voltage may be provided to the amplifier 640, in order to control an output of the amplifier arrangement 630. Using measurement circuit 660, for example comprising a resistor and an amplifier, an information, e.g. in the form of a voltage, about the output of the amplifier, namely the output current of the amplifier, may be provided to the currant adaptation circuit 650. As shown, the current adaptation circuit 650 may, for example, be a current source. Said current source may provide a current that is proportional to the output current, e.g. as shown a current of 20 mA, corresponding to an output current of 20 A, to the force pin 612. The module 610 may hence determine the information about the output current. In addition, using sense pin 614 module 610 may be configured to determine an information about an output voltage of the amplifier.

As shown, this way, one single channel may provide full control and measurement functionality for providing a desired voltage or respectively a desired current, within predefined current or respectively voltage intervals. Hence, a second module 620 may address another amplifier instead of providing a measurement functionality for the amplifier arrangement 630.

A high voltage amplifier, e.g. an op amp may be gaining the voltage coming from an analog pin, e.g. by a factor of 100, e.g. a factor of at least 10. With for example 3 current ranges 1 mA, 100 uA, 10 uA leakage measurements may be possible, e.g. from 0V up to +800V.

The measured current may be mirrored back to the connected analog pin. A current adaptation circuit, e.g. comprising a voltage to current converter may be used for this. In the block diagram of FIG. 4, this is the box 420a (V-I Converter). Apart from FIG. 4, reference is made to FIGS. 5 and 6 and in particular HV800.

And this is one or even the special idea according to embodiments. Instead of using another channel (e.g. a module 620 as shown in FIG. 6) and measuring the voltage coming from the current meas amp—the same channel can measure the current from the mirrored current. This safes another channel and has additional features which is not possible if another channel measure the output current.

Another or even the most benefit may be: Since the current is transferred from high voltage to the low voltage side, all functionality from the module, e.g. an AVI64 channel, can be used. Current clamp can be used, current bandwidth, slew rates. Voltage and current digitizing is possible on one analog pin with this principle. It may act or behave like a true high voltage pin—e.g. with very low effort. As an example, only scaling factors may need to be adjusted in the software. This can be done by the user.

Hence, embodiments provide a simple approach to get high voltages and/or to get high current out of an analog ATE pin. There may be no need to develop a whole new amplifier system, e.g. 93K instrument which is very expensive with high effort. Hence, embodiments, may provide a low cost solution addressing customer with low pin count and special need which cannot be addressed with existing instruments.

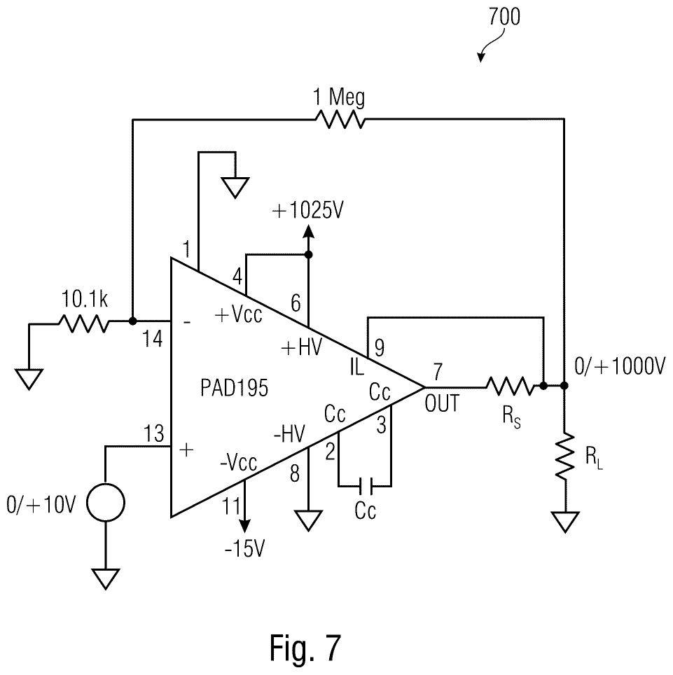

FIG. 7 shows schematic view of an amplifier according to embodiments of the invention. FIG. 7 shows amplifier 700 with respective input, output and supply signals. It is to be noted that the values and parameters denoted in FIG. 7 are to be seen as examples with tolerances, such that embodiments may comprise amplifiers as shown in FIG. 7 with parameter variations of e.g. +/−1%, +/−5%, +/−10%, +/−50%, +/−100%, +/−500% and/or +/−1000%.

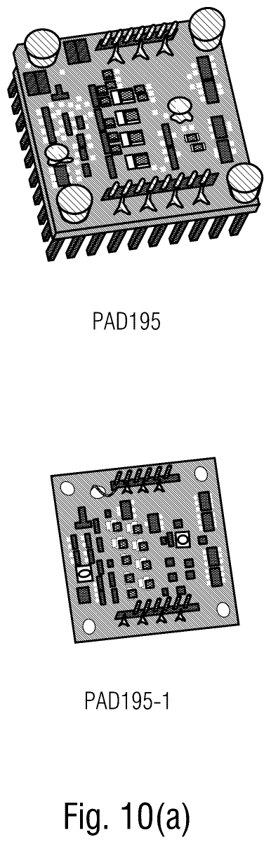

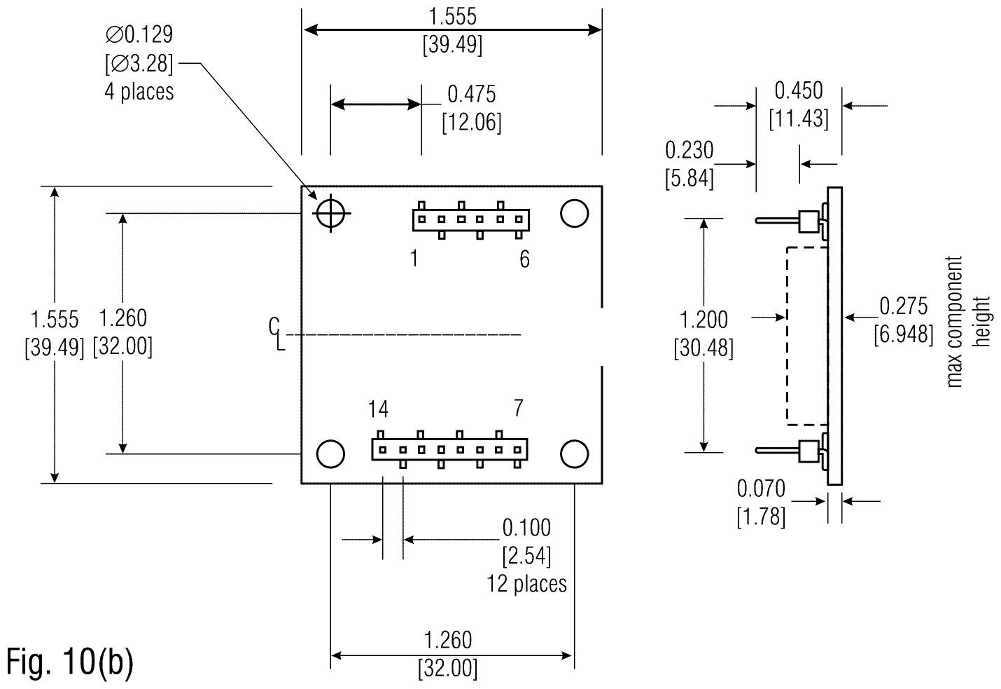

Key features of amplifiers according to embodiments of the invention may be low costs, e.g. of less or equal than 115€/100 pieces, small size (see e.g. FIG. 10 as an example), e.g. sizes of 40 mm square, e.g. of at least 20 mm square and at most 80 mm square, high voltages, e.g. of 1040V, e.g. of at least 520V and at most 2080V, output currents of e.g. 100 mA, e.g. of at least 50 mA and at most 200 mA, dissipation capabilities of e.g. 10 Watt, e.g. of at least 5 Watt and at most 20 Watt, slew rates of e.g. 3V/μS, e.g. of at least 1.5V/μS and at most 6V/μS and/or quiescent current of e.g. 1 mA, e.g. of at least 0.5 mA and at most 2 mA.

Applications for amplifiers or amplifier arrangements according to embodiments may, for example, be high voltage instrumentation, piezo transducer drives, electron beam focusing and/or programmable voltage sources.

Amplifiers may support unsymmetrical supply voltages of e.g. −50V to +1000V. Furthermore, the amplifier may be a programmable voltage source, e.g. a 1000V programmable voltage source. In general, amplifiers may comprise compact high voltage OP amps.

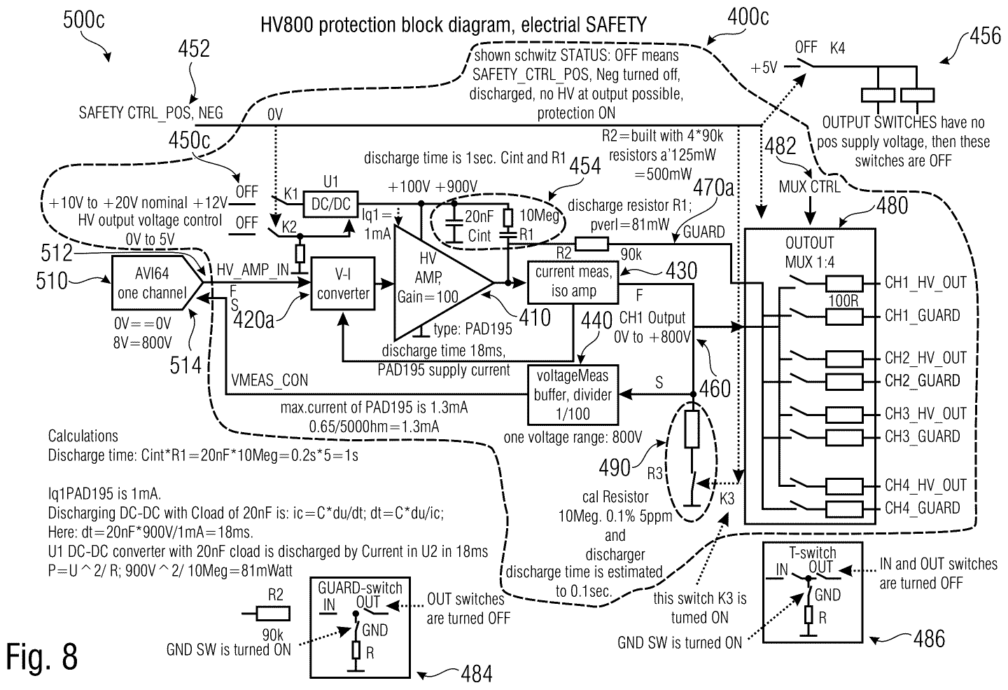

FIG. 8 shows a schematic view of an amplifier system with optional safety features according to embodiments of the invention. FIG. 8 shows amplifier system 500c comprising module 510, e.g. as explained before, and an amplifier arrangement 400c with elements as explained before. In contrast to FIGS. 4 and 5, amplifier arrangement 400c comprises additional discharge circuitry 454, as an example a capacitor which is coupled in parallel with a resistor. Furthermore, the safety module 450c is not integrated in the DC/DC converter but comprises switches K1 and K2 (and a resistor).

As shown in FIG. 8 in a safety mode, switches K1 and K2 may be open, such that the amplifier 410 does not receive a supply voltage. Using circuitry 454, remaining charge may be discharged. Furthermore, switch K3 of the calibration circuit may be closed in order to discharge the output of the amplifier. Accordingly, guard switches 484 may be toggled, such that an output of the switch is disconnected from ground, and such the input of the switch is connected to ground. T-switches 486 may be toggled, such that input and output of the switch may both be in an open switch state, such that charge in between input and output is discharged over a closed switch coupled with ground. Furthermore, for MUX 480, as shown with detail view 456, switches may be open, and hence switched OFF.

In the following, examples for calculation, parametrizations and/or discharging times are given for the embodiment shown in FIG. 8. It is to be noted, that these calculations are examples, and values and a parameters used therein are to be seen as values and parameters within a tolerance of e.g. +/−1%, +/−5%, +/−10%, +/−50%, +/−100%, +/−500% and/or +/−1000%.

Calculations: Discharge time: Cint*R1=20 nF*10 Meg=0.2 s*5=1 s; Iq1 PAD195 may, for example, be 1 mA. Discharging DC-DC with Cload of 20 nF may, for example, be: ic=C*du/dt; dt=C*du/ic; Here, as an example: dt=20 nF*900V/1 mA=18 ms. U1 DC-DC converter with 20 nF cload may, for example, be discharged by Current in U2 in 18 msP=U\hat{ }2/R; 900V\hat{ }2/10 Meg=81 mWatt.

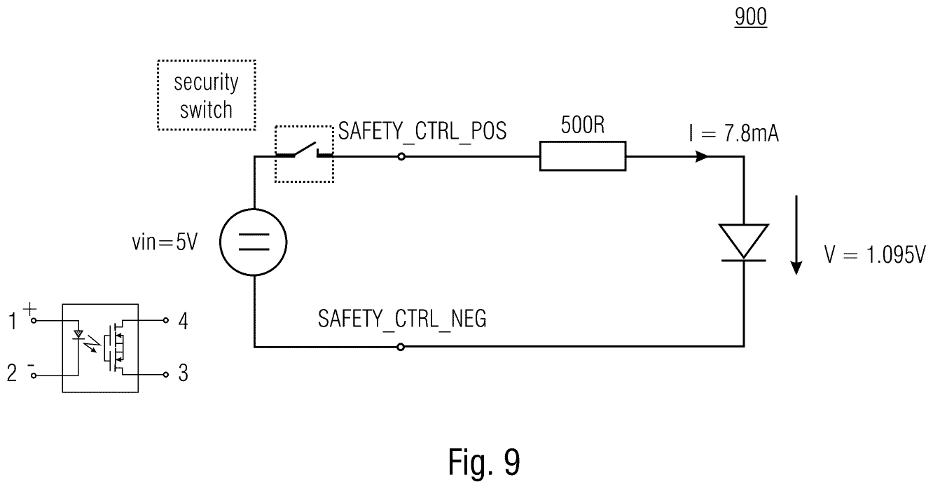

FIG. 9 shows a schematic view of a security switch according to embodiments of the invention. FIG. 9 shows a circuit 900 e.g. for providing signal 452 from FIGS. 4, 5 and 8. Again the parametrization is to be seen as an example, e.g. with tolerances of +/−1%, +/−5%, +/−10%, +/−50%, +/−100%, +/−500% and/or +/−1000%. On the left hand side, an example for an implementation for a switch is shown, hence embodiments may comprise a galvanic decoupling.

With regard to FIG. 9 embodiments may comprise the following characteristics: Switches: AQY278B switches, e.g. with 2 kV, e.g. 25 mA cont and e.g. 75 mA peak 100 ms single shoot; Leakage measurement+−0.2 nA at +−505V, 90 pA at +−10V, Leakage spec. 1 uA, Ron spec. (350 . . . 500) Ohm, Switching time: (0.2 . . . 1) ms; C iso 1.5 pF input to output, Coff=60 pF measured pin 3 to pin 4.

FIG. 10 shows a) further examples of amplifiers and b) an example for dimensions of an amplifier in a schematic view of an amplifier according to embodiments of the invention.

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus.

Depending on certain implementation requirements, embodiments of the invention can be implemented in hardware or in software. The implementation can be performed using a digital storage medium, for example a floppy disk, a DVD, a CD, a ROM, a PROM, an EPROM, an EEPROM or a FLASH memory, having electronically readable control signals stored thereon, which cooperate (or are capable of cooperating) with a programmable computer system such that the respective method is performed.

Some embodiments according to the invention comprise a data carrier having electronically readable control signals, which are capable of cooperating with a programmable computer system, such that one of the methods described herein is performed.

Generally, embodiments of the present invention can be implemented as a computer program product with a program code, the program code being operative for performing one of the methods when the computer program product runs on a computer. The program code may for example be stored on a machine readable carrier.

Other embodiments comprise the computer program for performing one of the methods described herein, stored on a machine readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) comprising, recorded thereon, the computer program for performing one of the methods described herein.

A further embodiment of the inventive method is, therefore, a data stream or a sequence of signals representing the computer program for performing one of the methods described herein. The data stream or the sequence of signals may for example be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, the methods are performed by any hardware apparatus.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. An amplifier arrangement, the amplifier arrangement comprising:
a control input,
an amplifier, and
a current adjustment circuit;
wherein the amplifier is configured to be controlled by a voltage at the control input of the amplifier arrangement; and
wherein the current adjustment circuit is configured to set a current at the control input of the amplifier arrangement in dependence on an output current of the amplifier arrangement.

2. The amplifier arrangement according to claim 1,
wherein the amplifier comprises a control input;
wherein the control input of the amplifier is a high impedance input; and
wherein the control input of the amplifier is coupled with the control input of the amplifier arrangement.

3. The amplifier arrangement according to claim 1, further comprising:
a measurement circuit;
wherein the measurement circuit is coupled with an output of the amplifier; and
wherein the measurement circuit is configured to provide an information about the output current of the amplifier arrangement to the current adjustment circuit in order to determine the current at the control input of the amplifier arrangement.

4. The amplifier arrangement according to claim 3,
wherein the measurement circuit is configured to be adjusted for evaluating the output current of the amplifier arrangement in a plurality of predetermined current ranges.

5. The amplifier arrangement according to claim 3,
wherein the measurement circuit is a current-to-voltage converter; and
wherein the current adjustment circuit is a voltage-to-current converter.

6. The amplifier arrangement according to claim 1, further comprising:
a measurement circuit;
wherein the measurement circuit is configured to provide an information about the output current of the amplifier arrangement to the current adjustment circuit in order to set the current at the control input of the amplifier arrangement to be a scaled version of the output current of the amplifier arrangement.

7. The amplifier arrangement according to claim 1,
wherein the amplifier is configured to provide an output voltage of the amplifier arrangement, such that the output voltage is at least by a factor of 10 or at least by a factor of 50 larger than the voltage at the control input of the amplifier arrangement.

8. The amplifier arrangement according to claim 1,
wherein the amplifier is configured to provide an output current of the amplifier arrangement,
such that the output current is at least by a factor of 10 or at least by a factor of 50 larger than a current that is provided at the control input of the amplifier arrangement, and/or
such that a maximum output current of the amplifier is at least by a factor of 10, or at least by a factor of 50, larger than a maximum output current of a channel module coupled to the input of the amplifier arrangement.

9. The amplifier arrangement according to claim 1, further comprising:
an output line, and
a guard line;
wherein the output line is configured to provide an output signal of the amplifier arrangement;
wherein the guard line is configured to provide a voltage associated with the output signal of the amplifier arrangement, and
wherein the guard line is arranged in a surrounding of the output line, in order to reduce or prevent a leakage current from the output line.

10. The amplifier arrangement according to claim 1, further comprising:
a multiplexer, and
a plurality of output channels;
wherein the multiplexer is configured to provide an output signal of the amplifier and a voltage associated with the output signal of the amplifier to a respective output channel of the plurality of output channels,
wherein the respective output channel comprises an output line, for providing the output signal, and a corresponding guard line, for providing the voltage associated with the output signal, in order to prevent a leakage of current from the output line.

11. The amplifier arrangement according to claim 10,
wherein the multiplexer comprises a first set of switches and a second set of switches,
wherein a respective switch of the first set of switches is configured to provide the voltage associated with the output signal of the amplifier arrangement to a respective guard line of a respective output channel out of the plurality of output channels;
wherein a respective switch of the second set of switches is configured to provide the output signal of the amplifier arrangement to a respective output line of a respective channel; and
wherein the switches of the second set of switches comprise a T-switch topology.

12. The amplifier arrangement according to claim 1, further comprising:
a calibration circuit, and
an output;
wherein the calibration circuit is configured to be coupled with the output of the amplifier arrangement, in order to allow for determination of a calibration information for the current at the control input of the amplifier arrangement.

13. Amplifier system comprising
an amplifier arrangement according to claim 1; and
a module,
wherein the module is coupled with the control input of the amplifier arrangement;
wherein the module is configured to provide the voltage to the control input of the amplifier arrangement; and
wherein the module is configured to determine an information about the current at the control input of the amplifier arrangement.

14. The amplifier system according to claim 13,
wherein the module is configured to acquire an information about an output voltage of the amplifier arrangement.

15. The amplifier system according to claim 13,
wherein the module comprise a force pin;
wherein the force pin is coupled with the control input of the amplifier arrangement; and
wherein the module is configured to provide the voltage to the control input of the amplifier arrangement using the force pin; and
wherein the current adjustment circuit is configured to provide the set current to the force pin.

16. The amplifier system according to claim 15,
wherein the module comprises a sense pin;
wherein the sense pin is coupled with an output of the amplifier arrangement;
wherein the sense pin is associated with the force pin, but wherein the sense pin is different from the force pin; and
wherein the module is configured to acquire the information about the output voltage of the amplifier arrangement using the sense pin.

17. The amplifier system according to claim 13,
wherein the module is configured to control a slew rate and/or a bandwidth of the amplifier.

18. The amplifier system according to claim 13,
wherein the amplifier arrangement is a high voltage circuit;
wherein the module is a low voltage circuit, comprising a low voltage output,
wherein the low voltage output is configured to provide an output voltage to the control input of the amplifier arrangement; and
wherein the low voltage circuit is configured to drive the high voltage circuit.

19. The amplifier system according to claim 13,
wherein a voltage range of an output voltage of the amplifier exceeds a voltage range of an output voltage of the module at least by a factor of 10 or at least by a factor of 50.

20. A method for operating an amplifier arrangement, the method comprising:
controlling an amplifier of the amplifier arrangement with a voltage at a control input of the amplifier arrangement; and
setting a current at the control input of the amplifier arrangement in dependence on an output current of the amplifier arrangement.
